(19) United States
(12) Patent Application Publication
(10) Pub. No.: US 2016/0026079 A1
(43) Pub. Date: Jan. 28, 2016

(54) MASK PATTERN CORRECTING METHOD

(71) Applicant: KABUSHIKI KAISHA TOSHIBA, Minato-ku (JP)

(72) Inventors: Taiki KIMURA, Yokohama (JP); Toshiya Kotani, Machida (JP); Masanori Takahashi, Yokohama (JP)

(73) Assignee: KABUSHIKI KAISHA TOSHIBA, Minato-ku (JP)

(21) Appl. No.: 14/608,429

(22) Filed: Jan. 29, 2015

Related U.S. Application Data
(60) Provisional application No. 62/029,024, filed on Jul. 25, 2014.

(51) Int. Cl. G03F 1/36; G06F 17/50

(52) U.S. Cl. CPC G03F 1/36; G06F 17/5081

(57) ABSTRACT

A mask pattern correcting method according to an embodiment is a correcting method of a mask pattern to be used in a semiconductor device manufacturing process. In the correcting method, a plurality of kernels calculated based on an optical system of an exposure tool is prepared. Weight coefficients for weighting the kernels, respectively, to be used when the kernels are synthesized, are calculated. The kernels are synthesized using the calculated weight coefficients. The mask pattern is corrected using the synthesized kernels.

### CROSS REFERENCE TO RELATED APPLICATIONS

This application is based upon and claims the benefit of priority from the prior US Provisional Patent Application No. 62/029,024 filed on Jul. 25, 2014, the entire contents of which are incorporated herein by reference.

### FIELD

The embodiments of the present invention relate to a mask pattern correcting method.

### BACKGROUND

A mask pattern for photolithography used in a manufacturing step of a semiconductor device is generated by performing an optical proximity correction (hereinafter, OPC) to address downscaling of the semiconductor device.

In the conventional OPC, a mask pattern is corrected using a single TCC (Transmission Cross Coefficient). With the conventional TCC, a mask pattern is optimized in terms of a resist dimension (a line width) without optimized in terms of optical image intensity. Accordingly, when a mask pattern generated using the conventional TCC is employed, a resist pattern is formed in such a manner that an average dimension in the film thickness direction (the height direction) or a dimension at a specific height position is as targeted while the resist pattern may be unsatisfactory in the entire shape, a shortage (a reduction) of a resist residual film, resist residues (trails), or the like. If a base material is processed using such a resist, the base material cannot be processed into a desired width or shape. Therefore, it is desirable to perform OPC processing of a mask pattern also in consideration of a shape of the resist in the film thickness direction (that is, a width or shape of the base material after processing).

### BRIEF DESCRIPTION OF THE DRAWINGS

FIG. 1 is a block diagram showing an example of a mask pattern correcting device 1 according to the present embodiment;

FIG. 2 is a flowchart showing an example of the mask pattern correcting method according to the present embodiment;

FIG. 3 is a graph showing a relation between the initial threshold Iinit and the weighting threshold Ith;

FIG. 4 is a conceptual diagram showing an example of a calculating method of the mask correction value using the blend TCC;

FIG. 5 is a flowchart showing an example of the calculating method of the mask correction value using the blend TCC;

FIG. 6 is a conceptual diagram showing an example of control points CPT of a mask pattern and a mask area setting;

FIG. 7 is a conceptual diagram showing the OPC processing using the normal TCC; and

FIGS. 8A to 8C are conceptual diagrams showing an OPC correction using the blend TCC.

### DETAILED DESCRIPTION

Embodiments will now be explained with reference to the accompanying drawings. The present invention is not limited to the embodiments.

A mask pattern correcting method according to an embodiment is a correcting method of a mask pattern to be used in a semiconductor device manufacturing process. In the correcting method, a plurality of kernels calculated based on an optical system of an exposure tool is prepared. Weight coefficients for weighting the kernels, respectively, to be used when the kernels are synthesized, are calculated. The kernels are synthesized using the calculated weight coefficients. The mask pattern is corrected using the synthesized kernels.

### First Embodiment

A mask pattern correcting method according to the present embodiment is a method of performing OPC processing of a mask design pattern when a mask pattern for photolithography used in a manufacturing step of a semiconductor device is formed. The mask pattern correcting method according to the present embodiment is executed using computer hardware and software.

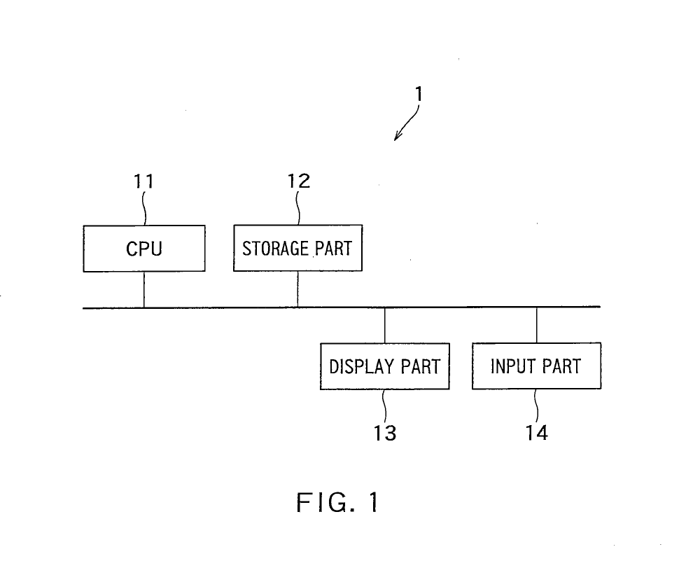

FIG. 1 is a block diagram showing an example of a mask pattern correcting device 1 (hereinafter, “device 1”) according to the present embodiment. The device 1 can be a computer including a CPU (Central Processing Unit) 11 serving as an arithmetic part, a storage part 12, a display part 13, and an input part 14.

The CPU 11 of the device 1 executes a mask pattern correcting method according to the present embodiment. In the mask pattern correcting method according to the present embodiment, for a certain control point, a plurality of kernels each being obtained with respect to each height of a resist pattern or each exposure focus are weighted and then the weighted kernels are synthesized into one kernel. In the mask pattern correcting method, the OPC processing is performed using the synthesized kernel.

A kernel (an integration kernel) is a function that represents an optical system of an exposure tool and is used when a resist pattern or a processing pattern of a processing target material is simulated based on a mask pattern. The kernel can be, for example, the TCC, a SOCS (Sum Of Coherent Systems), a PSF (Point Spread Function), a Bessel function, or the like. The TCC is used as an example of the kernel in the following embodiment. A TCC obtained by weighting a plurality of TCCs and synthesizing the weighted TCCs is hereinafter referred to as “blend TCC”.

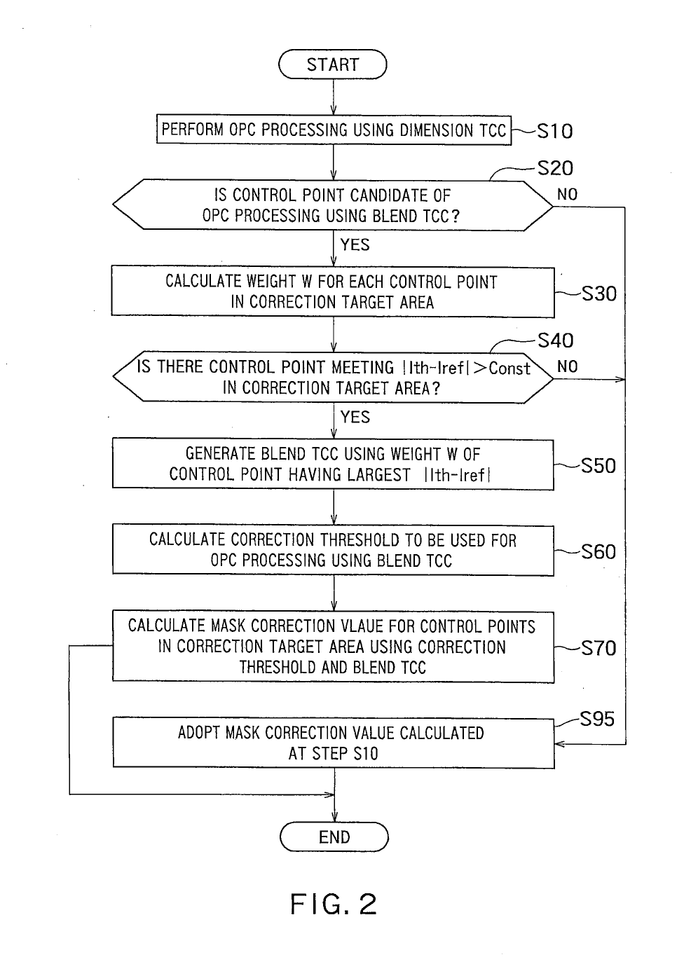

FIG. 2 is a flowchart showing an example of the mask pattern correcting method according to the present embodiment. The CPU 11 first performs OPC processing of a mask design pattern using a TCC which is a normal TCC being not blended (hereinafter, also simply “normal TCC”) (Step S10). At that time, an optical mage is modulated with the same model as that of an LCC (Lithography Compliance Check).

The CPU 11 then determines whether a control point of a mask pattern is a candidate of OPC processing using the blend TCC (Step S20). For example, when a line width or a space width in a certain mask pattern is smaller than a predetermined value (YES at Step S20), the CPU 11 determines that a relevant control point of the mask pattern is a candidate of the OPC processing using the blend TCC. This is because the area of the mask pattern has a relatively high possibility of being a hot spot in this case.

Meanwhile, when the line width or the space width in the mask pattern is equal to or larger than the predetermined value (NO at Step S20), the CPU 11 determines that the control point of the mask pattern is not a candidate of the OPC processing using the blend TCC. In this case, the CPU 11 adopts a mask correction value calculated at Step S10 (Step S95). This is because the relevant area of the mask pattern has a relatively low possibility of being a hot spot in this case.

When the control point is a candidate of the OPC processing using the blend TCC (YES at Step S20), the CPU 11 then calculates a weight coefficient for each of control points located within a correction target area including the control point determined as the candidate (Step S30). The weight coefficient is a blend ratio for each of TCCs applied when the blend TCC is calculated. The TCCs include those corresponding to division layers that are obtained by dividing the resist pattern in the height direction or those obtained when exposure focuses in the division layers are brought to positively defocused states or negatively defocused states, respectively. The CPU 11 calculates a weight coefficient with respect to each of the TCCs and adds the TCCs together after being weighted with the corresponding weight coefficients to calculate one blend TCC. The blend TCC is generated for each of correction target areas.

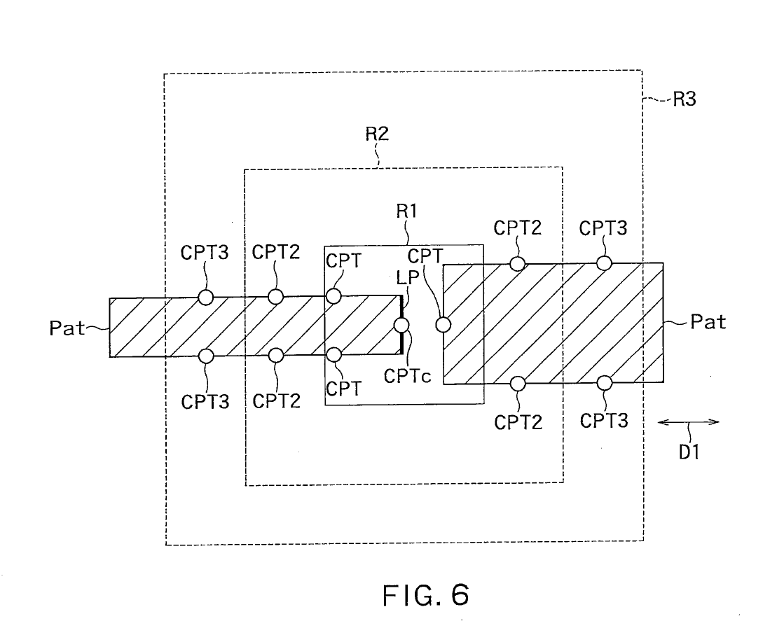

A correction target area is an area for which a correction is performed using a common blend TCC and mask patterns of control points within a correction target area are corrected using the common blend TCC. The correction target area will be explained later with reference to FIG. 6.

A calculation of the weight coefficient is explained in more detail. An optical image in this case is modulated with the same model as that in a verifying method of detecting a failure after processing.

In this case, n (n is an integer) TCCs for a time of dividing a resist at a certain control point (a first pattern portion) into m (m is an integer equal to or larger than two) layers in the film thickness direction (the height direction) and moving a focus position in each of the layers (division layers) are assumed. That is, m is a division number by which the resist is divided in the film thickness direction and n is the number of focal planes at the time of negative defocusing or positive defocusing in each of the division layers of the resist. The CPU 11 obtains a peak value i_{hotspot m,n} of optical image intensity (a feature amount) of the control point using the TCC of each division layer and each focus. When the peak value i_{hotspot m,n} is represented with a matrix of m rows and n columns, Hₚₑₐₖ as shown by Expression 1 is obtained.

$${H}_{peak} = ( \begin{matrix}{i}_{hotspot 0 , 0} & … & {i}_{hotspot 0 , n} \\ ⋮ & ⋱ & ⋮ \\ {i}_{hotspot m , 0} & … & {i}_{hotspot m , n}\end{matrix} ) \qquad Expression 1$$

Also for a reference pattern (a second pattern portion) in the mask pattern used to determine an exposure condition, a peak value i_{ref m,n} of the optical image intensity is similarly obtained using the TCC of each layer and each focus. When the peak value i_{ref m,n} is represented with a matrix of m rows and n columns, Rₚₑₐₖ as shown by Expression 2 is obtained.

$${R}_{peak} = ( \begin{matrix}{i}_{ref 0 , 0} & … & {i}_{ref 0 , n} \\ ⋮ & ⋱ & ⋮ \\ {i}_{ref m , 0} & … & {i}_{ref m , n}\end{matrix} ) \qquad Expression 2$$

A difference between the peak value i_{hotspot m,n} of the optical image intensity and the peak value i_{ref m,n} of the optical image intensity of the reference pattern is then calculated. A difference Dₚₑₐₖ as shown by Expression 3 is thereby obtained as an evaluation value. In this case, d_{m,n} is i_{hotspot m,n}−i_{ref m,n}.

$${H}_{peak} - {R}_{peak} = {D}_{peak} = ( \begin{matrix}{d}_{ 0 , 0} & … & {d}_{ 0 , n} \\ ⋮ & ⋱ & ⋮ \\ {d}_{ m , 0} & … & {d}_{ m , n}\end{matrix} ) \qquad Expression 3$$

A weigh coefficient W_{B,C} as shown by Expression 4 is calculated based on the difference Dₚₑₐₖ between the peak value i_{hotspot m,n} of the optical image intensity of the control point and the peak value i_{ref m,n} of the optical image intensity of the reference pattern.

$${W}_{B , C} = ( \begin{matrix}{B}^{{C}_{0 , 0} {d}_{0 , 0}} & … & {B}^{{C}_{0 , n} {d}_{0 , n}} \\ ⋮ & ⋱ & ⋮ \\ {B}^{{C}_{m , 0} {d}_{m , 0}} & … & {B}^{{C}_{m , n} {d}_{m , n}}\end{matrix} ) \qquad Expression 4$$

Although not particularly limited, B (Base) can be, for example, an exponential function. C_{m,n} can be a constant previously set. B and C_{m,n} can be set (changed) according to sensitivity or a processing resistance of the resist. Furthermore, B and C_{m,n} can be set (changed) based on any one or more of a structure of the processing target material, an NA (Numerical Aperture) of the exposure tool, an exposure wavelength, an exposure aberration, an illumination shape of the exposure, a defocusing condition of the exposure tool, a development condition, an etching processing condition, and the like.

W_{B,C} shown by Expression 4 can be used as it is as the weight coefficients (the blend ratios). This means that there are m×n weight coefficients in this case. Therefore, the CPU 11 weights all of the m×n TCCs, thereby obtaining one blend TCC.

The maximum value in each row can be alternatively used as the weight coefficient as shown by Expression 5. That is, the CPU 11 can keep the maximum one of TCCs calculated when the focus is changed in each division layer. In Expression 5, the maximum one of numerical values in each row is kept and the remaining numerical values are all replaced with zero. When there is a plurality of the maximum values in one row, it is possible to keep any one of the maximum values and set the others to zero. In the case of Expression 5, there are m weight coefficients. Therefore, the CPU 11 weights m TCCs to obtain one blend TCC. In this case, a load on the CPU 11 can be reduced.

$${W}_{row\_max} = ( \begin{matrix}{B}^{{C}_{0 , 0} {d}_{0 , 0}} & 0 & … & 0 \\ {B}^{{C}_{1 , 0} {d}_{1 , 0}} & 0 & … & 0 \\ ⋮ & & ⋱ & ⋮ \\ 0 & 0 & … & {B}^{{C}_{m , n} {d}_{m , n}}\end{matrix} ) \qquad Expression 5$$

The weight coefficient (the blend ratio) is calculated in this way. The weight coefficient W_{row}_{_{—}}ₘₐₓ is hereinafter referred to simply as “weight coefficient W”. The weight coefficient W is calculated based on the absolute value (|Hₚₑₐₖ−Rₚₑₐₖ|) of the difference between the peak value Hₚₑₐₖ of the optical image intensity and the peak value Rₚₑₐₖ of the optical image intensity of the reference pattern. The optical image intensity of the control point is obtained by a lithography simulation at the control point.

When the difference between the peak value Hₚₑₐₖ and the peak value Rₚₑₐₖ is large, a difference occurs between resist shapes, shortages (reductions) of resist residual films of the resist, resist residues (trails), or the like even when there is no difference between resist dimensions (average dimensions or dimensions at a predetermined position). Therefore, when the difference between the peak value Hₚₑₐₖ and the peak value Rₚₑₐₖ is large, the weight coefficient W (the blend ratio) is calculated to be large.

In the present embodiment, the CPU 11 uses the peak values of the optical image intensities as the feature amounts to calculate the weight coefficient W. However, it suffices that the feature amounts are amounts indicating resist shapes or processing shapes of the processing target material of the control point and the reference pattern and the feature amounts are not particularly limited. For example, the feature amounts can be the minimum values of the optical image intensities rather than the maximum values thereof. That is, the feature amounts can be extreme values of the optical image intensities. The feature amounts can be alternatively differential values of optical images or integral values of the optical images. The feature amounts can be resist widths in each of the division layers. The difference Dₚₑₐₖ is used as the evaluation value in the present embodiment. However, it suffices that the evaluation value is an amount indicating a difference (a gap) between the resist shapes or the shapes of the processing target material of the control point and the reference pattern and the evaluation value is not particularly limited. For example, the evaluation value can be a difference in differential values of optical images in each of the division layers or a difference in integral values of the optical images between the control point and the reference pattern. The evaluation value can be alternatively a difference in resist widths in each of the division layers between the control point and the reference pattern.

Referring back to FIG. 2, in order to determine whether to actually apply the blend TCC, |Ith−Iref| is then calculated with respect to each of control points in a correction target area (R1 in FIG. 6) of the mask pattern to compare |Ith−Iref| with a constant Const (Step S40). A weighting threshold Ith is a threshold of optical image intensity required to obtain a reference dimension as a target in the reference pattern after being weighted with the weight coefficient W. A reference threshold Iref is a threshold of an optical image intensity of the reference pattern in a case where the weight coefficient W is set to 1 (that is, Ith (W=1)). Therefore, |Ith−Iref| can be an index of changes in the optical image intensity of the reference pattern produced by weighting. The weight coefficient W is larger as the difference Dₚₑₐₖ between the peak value of the optical image intensity of the control point and the peak value of the optical image intensity of the reference pattern is larger. Therefore, |Ith−Iref| can be an index indicating a gap between an optical image of the reference pattern and an optical image of the control point.

A calculation of the weighting threshold Ith and the reference threshold Iref is explained in more detail. In this case, an optical image is modulated using the same model as that of an MCC.

A threshold of the reference pattern before weighting is assumed as an initial threshold Iinit. Similarly to the TCC, the initial threshold Iinit has values corresponding to the division layers and the focuses, respectively, and has m×n values. Therefore, the initial threshold Iinit is shown by Expression 6.

$${I}_{init} = ( \begin{matrix}{I}_{init 0 , 0} & … & {I}_{init 0 , n} \\ ⋮ & ⋱ & ⋮ \\ {I}_{init m , 0} & … & {I}_{init m , n}\end{matrix} ) \qquad Expression 6$$

The weighting threshold Ith is represented with the initial threshold Iinit and the weight coefficient W as shown by Expression 7.

Iₜₕ=ΣΣₘΣₙW_{m,n}I_{init m,n}/ΣₘΣₙW_{m,n} Expression 7

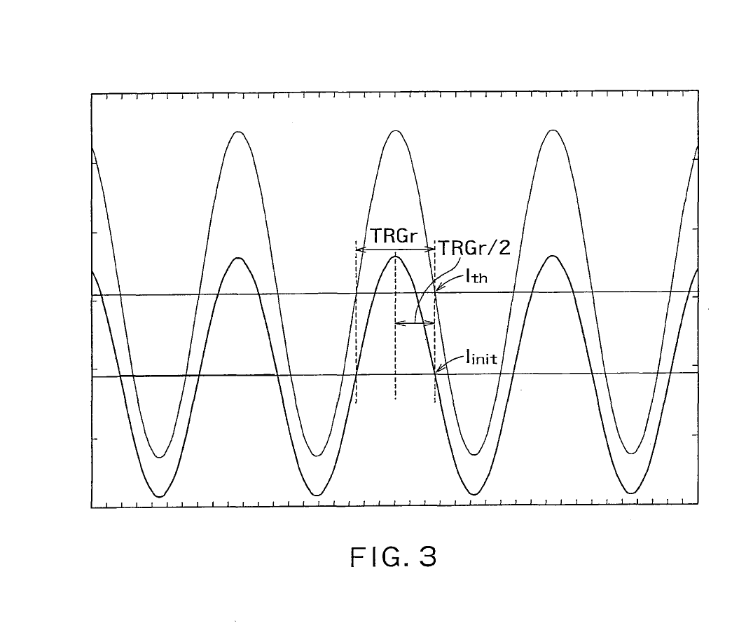

FIG. 3 is a graph showing a relation between the initial threshold Iinit and the weighting threshold Ith. The vertical axis represents the optical image intensity and the horizontal axis represents the distance (the dimension). A threshold of the optical image intensity is an optical image intensity at a position deviated from a peak of an optical image intensity by a half pitch (TRGr/2) of a reference dimension TRGr as a target. Therefore, the initial threshold Iinit is optical image intensity at a position deviated from a peak of an optical image intensity of the reference pattern before weighting by the half pitch (TRGr/2) of the reference dimension TRGr. The weighting threshold Ith is optical image intensity at a position deviated from a peak of an optical image intensity of the reference pattern after weighting by the half pitch (TRGr/2) of the reference dimension TRGr.

Even when weighting is performed, the initial threshold Iinit needs to be changed to the weighting threshold Ith as shown in FIG. 2 to equalize the reference dimension TRGr of the reference pattern. A new threshold used in the blend TCC is Ith.

The reference threshold Iref is the threshold Ith of a time when the weight coefficient W is 1. Therefore, as described above, the threshold difference |Ith−Iref| indicates a change in the threshold of the reference pattern produced by the weight coefficient W and can be an index indicating a gap between the optical image of the reference pattern and the optical image of the control point. The reference threshold Iref can be calculated by using an arbitrary pattern and setting all of C_{m,n} in Expression 4 mentioned above to zero, without being calculated using the reference pattern.

When there is a control point for which |Ith−Iref| is larger than the constant Const in the correction target area (R1 in FIG. 6) as a result of the comparison between |Ith−Iref| and the constant Const at Step S40 in FIG. 2 (YES at Step S40), the CPU 11 generates the blend TCC. That is, it is determined that the correction target area may become a hot spot only with the OPC processing using the normal TCC at Step S10.

Meanwhile, when there is no control point for which |Ith−Iref| is larger than the constant Const in the correction target area (NO at Step S40), the CPU 11 determines that the OPC processing using the blend TCC is not required for the control points in the correction target area. That is, it is determined that the correction target area does not become a hot spot only with the OPC processing using the normal TCC at Step S10. When the OPC processing using the blend TCC is not required, the CPU 11 adopts the mask correction value calculated at Step S10 (Step S95).

When there are control points for which |Ith−Iref| is larger than the constant Const (YES at Step S40), the CPU 11 then generates the blend TCC using the weight coefficient W of a control point for which |Ith−Iref| is the largest among control points in the correction target area (Step S50). The blend TCC is represented as TCC_{new} as shown by Expression 8.

TCC_{new}=ΣₘΣₙW_{m,n}TCC_{m,n}/ΣₘΣₙW_{m,n} Expression 8

The CPU 11 then calculates a correction threshold to be used for the OPC processing using the blend TCC (Step S60). The correction threshold
Iₜₕ^{correct}
   is shown by Expression 9.

Iₜₕ^{correct}=IₜₕB′^{C}′^{|I}^{ₜₕ}^{-I}^{_{ref}}^{|} Expression 9

where B′ is an arbitrary bottom (a real number) that adjusts the correction threshold and is, for example, an exponential function. C′ is an arbitrary constant (a real number) that adjusts the correction threshold. B′ and C′ are determined considering a condition of etching using the resist. Furthermore, B′ and C′ can be set (changed) based on any one or more of the structure of the processing target material, the NA of the exposure tool, the exposure wavelength, the exposure aberration, the illumination shape of the exposure, the defocusing condition of the exposure tool, the development condition, the etching processing condition, and the like. Hereinafter, the correction threshold
Iₜₕ^{correct}
   is represented as Ith_correct.

If a pattern of a control point is close to the reference pattern, |Ith−Iref| is close to zero. Therefore, the correction threshold Ith_correct is close to the reference threshold Ith. On the other hand, if the correction target pattern is deviated from the reference pattern, |Ith−Iref| is large and thus the correction threshold Ith_correct is largely deviated from the reference threshold Ith. In this way, the correction threshold Ith_correct changes depending on |Ith−Iref|.

The CPU 11 then performs the OPC processing using the correction threshold and the blend TCC, thereby calculating a mask correction value for the control points in the correction target area (Step S70). In this way, the mask correction value is calculated using the blend TCC in the present embodiment. The OPC processing shown in FIG. 2 is performed with respect to each of the correction target areas. The correction target area will be explained later with reference to FIG. 6.

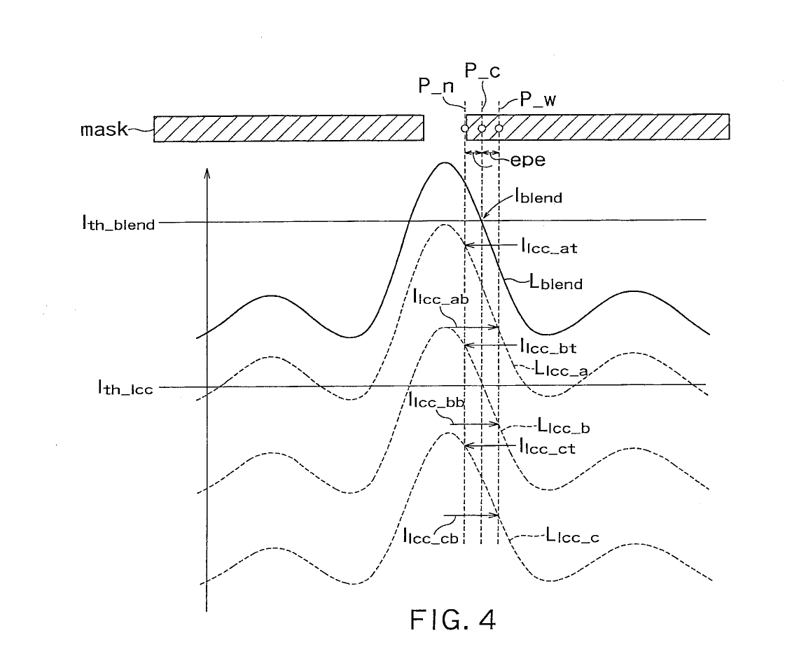

FIG. 4 is a conceptual diagram showing an example of a calculating method of the mask correction value using the blend TCC. Broken lines Llcc_a, Llcc_b, and Llcc_c show optical image intensities (hereinafter, “LCC optical image intensities”) calculated with the normal TCC. A solid line Lblend shows an optical image intensity (hereinafter, “blend optical image intensity”) calculated with the blend TCC. An LCC threshold Ith_lcc is a threshold of LCC optical image intensity and is not weighted. That is, the LCC threshold Ith_lcc is equal to the initial threshold Iinit. A blend threshold Ith_blend is a threshold of blend optical image intensity and is weighted. That is, the blend threshold Ith_blend is equal to the correction threshold Ith_correct.

At Step S10, an edge position of the mask pattern of a control point is assumed as P_c. A permissible deviation amount epe centered at the position P_c is set. A position of an opening of the mask widened from the position P_c by the permissible deviation amount epe is assumed as a permissible end P_w. A position of the opening of the mask narrowed from the position P_c by the permissible deviation amount epe is assumed as a permissible end P_n.

To position an end of the resist viewed from the top between the permissible end P_w and the permissible end P_n (hereinafter, also “permissible range P_w to P_n”), the LCC optical image intensity needs to be equal to the LCC threshold Ith_lcc at any of positions in the permissible range P_w to P_n. One end of the resist viewed from the top can be thereby positioned in the permissible range P_w to P_n. On the other hand, the blend optical image intensity is preferably as close as possible to the blend threshold Ith_blend at the position P_c. This is to form the resist into a desired height or shape and to cause the processing target material after etching processing to have a satisfactory shape. That is, to cause both of the dimension of the resist and the height or shape of the resist to be satisfactory, it is preferable that there is a point where the LCC optical image intensity is equal to the LCC threshold Ith_lcc in the permissible range P_w to P_n (a condition 1) and that the blend optical intensity is as close as possible to the blend threshold Ith_blend at the position P_c (a condition 2). The mask correction value of the control point is determined to cause the LCC optical image intensity and the blend optical intensity to meet the condition 1 and the condition 2, respectively.

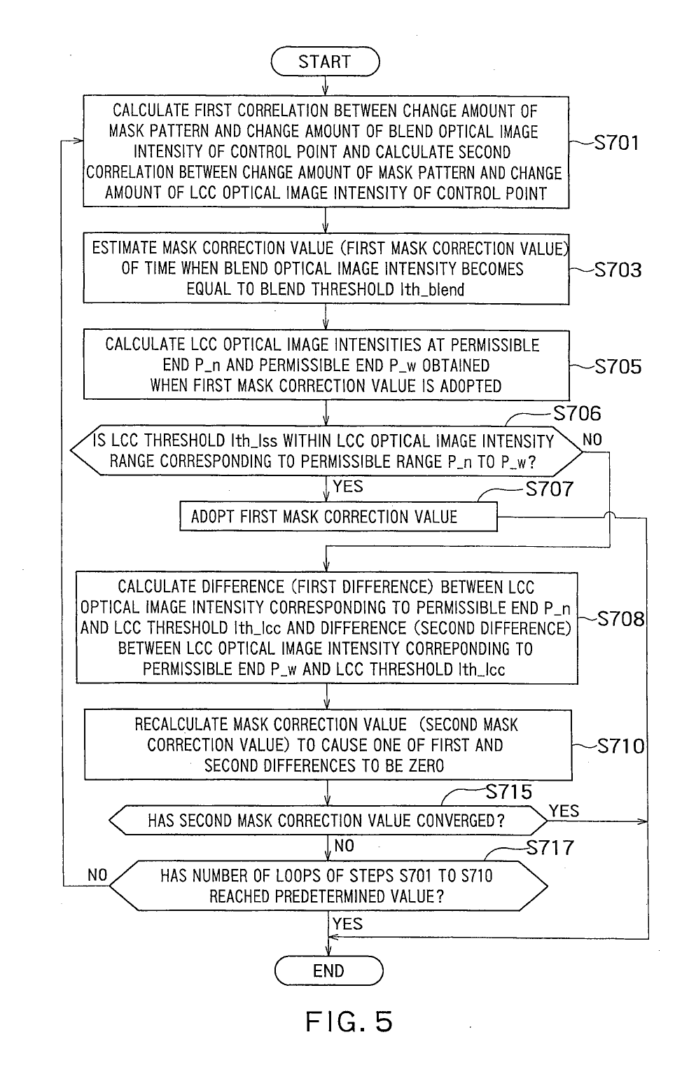

FIG. 5 is a flowchart showing an example of the calculating method of the mask correction value using the blend TCC. The calculating method of the mask correction value is explained with reference to FIGS. 4 and 5.

The CPU 11 first calculates a first correlation between the change amount of the mask pattern and the change amount of the blend optical image intensity of a control point. The CPU 11 also calculates a second correlation between the change amount of the mask pattern and the change amount of the LCC optical image intensity of the control point (Step S701). That is, how much the LCC optical image intensity and the blend optical image intensity of the control point are changed according to a deviation amount of the mask pattern is calculated.

The CPU 11 then estimates a first mask correction value of a time when the blend optical image intensity becomes equal to the blend threshold Ith_blend based on the first correlation (Step S703). The first mask correction value is represented as a shift amount of the mask pattern of the control point.

LCC optical image intensities at the permissible end P_n and the permissible end P_w obtained when the first mask correction value is adopted are then calculated based on the second correlation (Step S705). Accordingly, a range of the LCC optical image intensity corresponding to the permissible range P_n to P_w is known.

The CPU 11 then determines whether the LCC threshold Ith_lcc is within the range of the LCC optical image intensity corresponding to the permissible range P_n to P_w (Step S706).

When the LCC threshold Ith_lcc is within the range of the LCC optical image intensity corresponding to the permissible range P_n to P_w (YES at Step S706), the CPU 11 adopts the first mask correction value (Step S707). For example, when the LCC optical image intensity is as shown by the line Llcc_b in FIG. 4, the range of the LCC optical image intensity corresponding to the permissible range P_n to P_w is from Ilcc_bt to Ilcc_bb. In this case, the LCC threshold Ith_lcc is within the optical image intensity range Ilcc_bt to Ilcc_bb. Therefore, the first mask correction value is adopted as it is. In this example, Ilcc_bt is a value of the optical image intensity shown by the line Llcc_b at the permissible end P_n and Ilcc_bb is a value of the optical image intensity shown by the line Llcc_b at the permissible end P_w.

On the other hand, when the LCC threshold Ith_lcc is not within the range of the LCC optical image intensity corresponding to the permissible range P_n to P_w (NO at Step S706), the CPU 11 calculates a difference (a first difference) between the LCC optical image intensity corresponding to the permissible end P_n and the LCC threshold Ith_lcc and a difference (a second difference) between the LCC optical image intensity corresponding to the permissible end P_w and the LCC threshold Ith_lcc (Step S708). For example, when the LCC optical image intensity is as shown by the line Llcc_a in FIG. 4, the LCC optical image intensities corresponding to the permissible ends P_n and P_w are Ilcc_bt and Ilcc_ab, respectively. Therefore, the first difference is |Ilcc_at−Ith_Icc|. The second difference is |Ilcc_ab−Ith_Icc|. In this case, Ilcc_bt is a value of the optical image intensity shown by the line Llcc_a at the permissible end P_n and Ilcc_ab is a value of the optical image intensity shown by the line Llcc_a at the permissible end P_w. When the LCC optical image intensity is as shown by the line Llcc_c in FIG. 4, the LCC optical image intensities corresponding to the permissible ends P_n and P_w are Ilcc_ct and Ilcc_cb, respectively. Therefore, the first difference is |Ilcc_ct−Ith_Icc|. The second difference is |Ilcc_cb−Ith_Icc|. In this case, Ilcc_ct is a value of the optical image intensity shown by the line Llcc_c at the permissible end P_n and Ilcc_cb is a value of the optical image intensity shown by the line Llcc_c at the permissible end P_w.

The CPU 11 then recalculates the mask correction value to cause smaller one of the first and second differences to be zero (Step S710). That is, the mask correction value is recalculated to cause one of the LCC optical image intensities corresponding to the permissible ends P_n and P_w, which is relatively close to the threshold Ith_lcc, to be equal to the threshold Ith_lcc. For example, when the LCC optical image intensity is as shown by the line Llcc_a in FIG. 4, the second difference is smaller than the first difference. That is, Ilcc_ab is close to the threshold Ith_lcc than Ilcc_at. Therefore, at step S710, the CPU 11 recalculates the mask correction value to cause Ilcc_ab to be equal to the threshold Ith_lcc. When the LCC optical image intensity is as shown by the line Llcc_c in FIG. 4, the first difference is smaller than the second difference. That is, Ilcc_ct is close to the threshold Ith_lcc than Ilcc_cb. Therefore, the CPU 11 recalculates the mask correction value to cause Ilcc_cb to be equal to the threshold Ith_lcc. The mask correction value recalculated at Step S710 is hereinafter referred to as “second mask correction value”.

Steps S701 to S710 are repeated until the second mask correction value converges at the control point in a certain mask area (an operation target area R2 in FIG. 6) (Step S715). The mask correction value is determined in this way. Alternatively, the second mask correction value obtained when the number of loops of Steps S701 to S710 has reached a predetermined value is adopted (Step S717).

The mask correction value is determined as described above. The CPU 11 corrects the edge position of the mask pattern of the control point in the correction target area using the mask correction value. The mask pattern in the correction target area is thereby determined.

The device 1 also corrects each of other areas of the mask pattern as the correction target areas in a similar manner according to the flows shown in FIGS. 2 and 5. The whole mask pattern is thereby corrected.

### (Correction Target Area)

FIG. 6 is a conceptual diagram showing an example of control points CPT of a mask pattern and a mask area setting. The control points CPT are set to correspond to predetermined line segments of the mask pattern, respectively, and the mask pattern can be changed by moving line segments of the mask pattern. For example, when a line segment Lp of the mask pattern of a control point CPTc is moved in a D1 direction, a mask pattern Pat is changed. Because an optical image irradiated on a resist is changed when the mask pattern Pat of the control point CPTc is changed, an optical image of the control point CPTc can be calculated from the mask pattern Pat. The graph as shown in FIG. 4 is thereby obtained.

A correction target area R1 is a target area of a correction using the blend TCC. For example, in the case of YES at Step S40 in FIG. 2, mask patterns of all the control points CPT in the correction target area R1 are corrected with the mask correction value generated at Step S70.

Meanwhile, a mask pattern of control points CPT2 in an operation target area R2 other than the area R1 is not a correction target. However, the mask pattern of the control points CPT2 is operated when the first and second correlations and the first and second mask correction values are calculated at Steps S701, S703, and S710 in FIG. 5.

Furthermore, a mask pattern of control points CPT3 in a consideration target area R3 other than the areas R1 and R2 is neither a correction target nor operated. However, the control points CPT3 are considered to obtain an optical image.

Control points outside of the area R3 are distance from the correction target area R1 and thus are not considered in the mask correction in the correction target area R1.

Needless to mention, the mask area setting shown in FIG. 6 is merely an example and the device 1 can execute a mask pattern correcting method according to the present embodiment in other mask area settings. Even when included in the correction target area R1, mask patterns of control points that are not correction candidates at Step S20 in FIG. 2 can be kept fixed with no correction after the OPC processing is performed at Step S10. Furthermore, even when included in the correction target area R1, mask patterns of control points for which |Ith−Iref| is smaller than the constant Const at Step S40 can be kept fixed with no correction after the OPC processing is performed at Step S10.

### (Input Information)

Information input by an operator to the input part 14 shown in FIG. 1 includes Rₚₑₐₖ of Expression 2, B and C_{m,n} of Expression 4, Iinit of Expression 6, B′ and C′ of Expression 9, the constant Const at Step S40, and the permissible deviation amount epe shown in FIG. 4. After input to the input part 14, the information is stored in the storage part 12. The storage part 12 has a program for executing the above mask pattern correcting method stored therein. The information and the program are used when the CPU 11 executes the method according to the present embodiment.

The display part 13 displays information input from the input part 14, an arithmetic result obtained by the CPU 11, or the like. The display part 13 can display the graph shown in FIG. 2 or 4.

As described above, with the mask pattern correcting method according to the present embodiment, the device 1 weights a plurality of TCCs corresponding to division layers of a resist and a plurality of TCCs obtained when an exposure focus is brought to a defocused state and combines the weighted TCCs into one blend TCC. The weight coefficient W (the blend ratio) is determined based on a difference of resist image between the target pattern and the reference pattern. The weight coefficient W is desired to be larger for a TCC having a larger difference in the images. Accordingly, a blend TCC obtained by combining TCCs based on the weight coefficient W represents the difference of image intensity between a target pattern and reference pattern in the height direction of the resist. The OPC processing using the blend TCC can suppress occurrence of a hot spot more than the OPC processing using only the normal TCC.

Furthermore, according to the present embodiment, the mask correction value for control points is determined to meet the conditions 1 and 2 using both of the LCC optical image intensity using the normal TCC and the blend optical image intensity using the blend TCC. This thereby enables the OPC processing in consideration both of the dimension of the resist and the height or shape of the resist. As a result, occurrence of a hot spot can be suppressed.

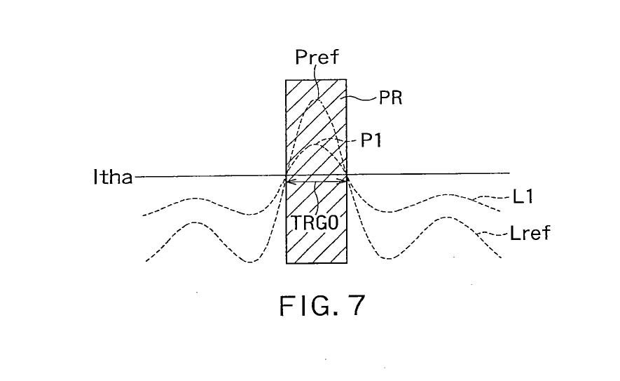

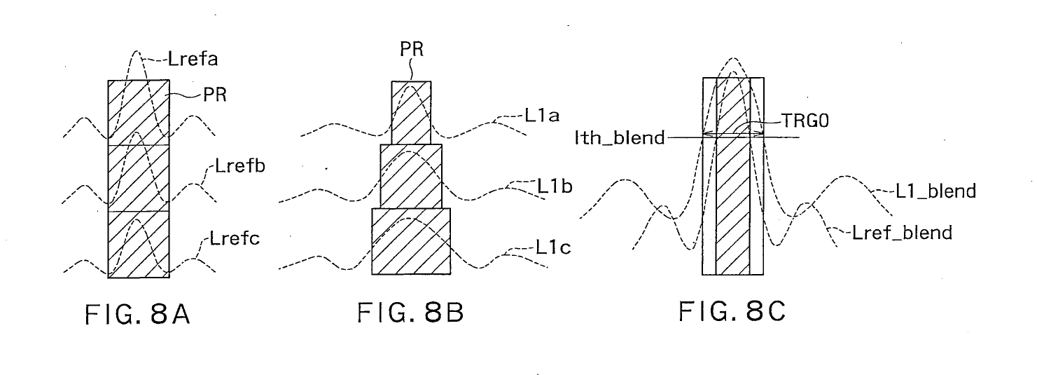

For example, FIG. 7 is a conceptual diagram showing the OPC processing using the normal TCC. A target dimension averaged in the height direction of a resist PR or a target dimension at a specific height position is denoted by TRG0. Furthermore, an optical image of the reference pattern is denoted by Lref and an optical image of a control point is denoted by L1. The optical images Lref and L1 have dimensions equal to the target dimension TRG0 at a threshold Itha. However, a peak P1 of the optical image intensity of the optical image L1 is much lower than a peak Pref of the optical image intensity of the optical image Lref. Therefore, even when the resist has a dimension viewed from the top almost equal to the target value, the height may be too low or the shape may be deteriorated. This may cause a hot spot. Meanwhile, FIGS. 8A to 8C are conceptual diagrams showing an OPC correction using the blend TCC. FIG. 8A shows optical images Lrefa to Lrefc of the reference pattern. The optical image Lrefa is an optical image on a division layer at a high position in the resist PR, the optical image Lrefb is an optical image on a division layer at an intermediate position in the resist PR, and the optical image Lrefc is an optical image on a division layer at a low position in the resist PR. FIG. 8B shows optical images L1a to L1c of a control point. The optical image L1a is an optical image on a division layer at a high position in the resist PR, the optical image L1b is an optical image on a division layer at an intermediate position in the resist PR, and the optical image L1c is an optical image on a division layer at a low position in the resist PR.

In this case, as shown in FIGS. 8A and 8B, at a higher position in the resist PR, a degree by which the peak of the optical image of the control point is lowered relative to the peak of the corresponding optical image of the reference pattern is larger. In this case, as shown in FIG. 8B, the resist PR of the control point becomes narrow at a high position or the resist PR possibly may be lost at a high position.

Accordingly, the weight coefficient W for the TCC of the optical image L1a having a large gap from the reference pattern is set large and the weight coefficient W for the TCC of the optical image L1c having a relatively small gap from the reference pattern is set small. By generating the blend TCC using these weight coefficients W, the TCC considering more a difference between the optical image Lrefa of the reference pattern and the optical image L1a can be generated.

When optical images are calculated using the blend TCC, an optical image Lref_blend of the reference pattern and an optical image L1_blend of the control point are obtained as shown in FIG. 8C. To keep the target dimension TRG0, the threshold Itha is changed to a blend threshold Ith_blend. At the blend threshold Ith_blend, the optical image L1_blend of the control point does not match the optical image Lref_blend and there is a deviation in the dimension. This dimension deviation is the amount of a difference (a gap) in the resist shape or the shape of the processing target material converted into a mask dimension. A correction using the mask dimension is thereby enabled.

As described above, by performing the OPC processing using the blend TCC, the mask correction value can be calculated considering the height or shape of the resist.

### (Modification)

In the embodiment mentioned above, the number of division layers in the resist is m. In the present modification, the number of division layers in the resist as a processing target is reduced to reduce the calculation amount of the CPU 11.

However, if the number of resist division layers for the TCCs is simply reduced, the feature amounts in the resist height direction are averaged and thus a difference in the feature amounts between the reference pattern and a pattern of a control point becomes small.

Therefore, in the present modification, the number of resist division layers for the TCCs is kept and the division layers to be used for a calculation of the weight coefficient W are thinned down. For example, the CPU 11 calculates the weight coefficient W using two layers of a top division layer located at an uppermost portion in the resist and a bottom division layer located at a lowermost portion therein. Intermediate division layers located between the top division layer and the bottom division layer are not considered in the calculation of the weight coefficient W. In this case, elements of the intermediate layers can be omitted as shown by Expression 10.

$$( \begin{matrix}{a}_{ 0 , 0} & {a}_{ 0 , 1} & … & {a}_{ 0 , n} \\ {a}_{ m , 0} & {a}_{ m , 1} & … & {a}_{ m , n}\end{matrix} ) \qquad Expression 10$$

Expression 10 is applied to Expressions 1 and 2 when the weight coefficient W is calculated. When Expression 10 is applied to Expression 1, it suffices to substitute I_{hotspot m,n} for a_{m,n}. When Expression 10 is applied to Expression 2, it suffices to substitute i_{ref m,n} for a_{m,n}. In this way, the calculation of the weight coefficient W is reduced and a load of the CPU 11 is reduced.

The present modification can be carried out by using the device 1. Other calculations in the present modification can be identical to the corresponding ones in the first embodiment. Therefore, the present modification can achieve effects identical to those of the first embodiment.

At least a part of the mask pattern correcting method according to the embodiment described above can be configured with hardware as described above or alternatively can be configured with software. When a part of the mask pattern correcting method is configured with software, a program that realizes at least a part of functions of the mask pattern correcting method can be stored in a recording medium such as a flexible disk or a CD-ROM and be read by a computer to execute the program. The recording medium is not limited to removable one such as a magnetic disk or an optical disk and can be a fixed recording medium such as a hard disk drive or a memory. The program that realizes at least a part of the functions of the mask pattern correcting method can be distributed via a communication line (including a wireless communication) such as the Internet. Furthermore, the program can be distributed via a wire circuit or a wireless circuit such as the Internet or by being stored in a recording medium in a state where the program is encrypted, modulated, or compressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A correcting method of a mask pattern to be used in a semiconductor device manufacturing process, the method comprising:
preparing a plurality of kernels calculated based on an optical system of an exposure tool;
calculating weight coefficients for weighting the kernels, respectively, to be used when the kernels are synthesized;
synthesizing the kernels using the calculated weight coefficients; and
correcting the mask pattern using the synthesized kernels.

2. The method of claim 1, wherein
the calculation of the weight coefficients comprises:
calculating first feature amounts related to resist shapes corresponding to a first pattern portion of the mask pattern with respect to the kernels, respectively;
calculating second feature amounts related to resist shapes corresponding to a second pattern portion of the mask pattern with respect to the kernels, respectively;
calculating evaluation values indicating gaps between the resist shapes corresponding to the first pattern portion and the resist shapes corresponding to the second pattern portion using the first feature amounts and the second feature amounts with respect to the kernels, respectively; and
calculating the weight coefficients based on the evaluation values with respect to the kernels, respectively.

3. The method of claim 2, wherein the evaluation value is a difference between the first feature amount and the second feature amount.

4. The method of claim 1, wherein the kernels are defined with respect to division layers generated by dividing a resist of the semiconductor device manufacturing process in a film thickness direction of the resist, respectively.

5. The method of claim 2, wherein the kernels are defined with respect to division layers generated by dividing a resist of the semiconductor device manufacturing process in a film thickness direction of the resist, respectively.

6. The method of claim 3, wherein the kernels are defined with respect to division layers generated by dividing a resist of the semiconductor device manufacturing process in a film thickness direction of the resist, respectively.

7. The method of claim 1, wherein the kernels are any one of a TCC (Transmission Cross Coefficient), a SOCS (Sum Of Coherent Systems), a PSF (Point Spread Function), or a Bessel function.

8. The method of claim 2, wherein the kernels are any one of a TCC (Transmission Cross Coefficient), a SOCS (Sum Of Coherent Systems), a PSF (Point Spread Function), or a Bessel function.

9. The method of claim 3, wherein the kernels are any one of a TCC (Transmission Cross Coefficient), a SOCS (Sum Of Coherent Systems), a PSF (Point Spread Function), or a Bessel function.

10. The method of claim 4, wherein the kernels are any one of a TCC (Transmission Cross Coefficient), a SOCS (Sum Of Coherent Systems), a PSF (Point Spread Function), or a Bessel function.

11. The method of claim 2, wherein the feature amounts are one of intensities of optical images calculated using the kernels and the first or second pattern portions, differential values of the optical images, and integral values of the optical images, respectively.

12. The method of claim 3, wherein the feature amounts are one of intensities of optical images calculated using the kernels and the first or second pattern portions, differential values of the optical images, and integral values of the optical images, respectively.

13. The method of claim 4, wherein the feature amounts are one of intensities of optical images calculated using the kernels and the first or second pattern portions, differential values of the optical images, and integral values of the optical images, respectively.

14. The method of claim 1, wherein calculating of the weight coefficients is performed based on any one or more of a structure of a processing target material, an NA (Numerical Aperture) of the exposure tool, an exposure wavelength, an exposure aberration, an illumination shape of an exposure, a defocusing condition of the exposure tool, a development condition, an etching processing condition.

15. The method of claim 4, wherein the kernels are defined with respect to focuses when focuses of the exposure tool are changed for the division layers, respectively.

16. The method of claim 15, wherein maximum one of the weight coefficients calculated for each focus is kept and remaining ones of the weight coefficients are set to zero with respect to the division layers, respectively.

17. The method of claim 4, wherein one of the weight coefficients, the weight coefficient being calculated for predetermined one of the division layers of the resist, is kept and ones of the weight coefficients calculated for other division layers are omitted.

18. A correcting device of a mask pattern to be used in a semiconductor device manufacturing process, the device comprising an arithmetic part configured to:
prepare a plurality of kernels calculated based on an optical system of an exposure tool;
calculate weight coefficients for weighting the kernels, respectively, to be used when the kernels are synthesized;
synthesize the kernels using the calculated weight coefficients; and
correcting the mask pattern using the synthesized kernels.
